(19) United States
(12) Patent Application Publication
(10) Pub. No.: US 2009/0087988 A1
(43) Pub. Date: Apr. 2, 2009

(54) POLISHING LIQUID AND POLISHING METHOD

(75) Inventor: Toshiyuki Saie, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/235,475

(22) Filed: Sep. 22, 2008

(30) Foreign Application Priority Data
Sep. 28, 2007 (JP) 2007-256304

(51) Int. Cl. H01L 21/304; C09K 13/00

(52) U.S. Cl. 438/693; 252/79.1; 257/E21.239

(57) ABSTRACT

A polishing liquid is provided which is used for polishing a barrier layer of a semiconductor integrated circuit, the polishing liquid including surface modified particles that include organic polymer particles having at least one inorganic atom selected from the group consisting of Ti, Al, Zr and Si bonded to the organic polymer particles via an oxygen atom present on a surface of the organic polymer particles, an organic acid, an azole compound having at least two carboxyl groups, and an oxidizing agent, the polishing liquid having a pH of from 1 to 7; and a polishing method for polishing a barrier layer of a semiconductor integrated circuit is also provided.

### CROSS-REFERENCE TO RELATED APPLICATION

This application claims priority under 35 USC 119 from Japanese Patent Application No. 2007-256304, the disclosure of which is incorporated by reference herein.

### BACKGROUND OF THE INVENTION

1. Technical Field

The present invention relates to a polishing liquid and a polishing method.

2. Description of the Related Art

In recent years, in the development of semiconductor devices as represented by semiconductor integrated circuits (hereinafter referred to as “LSI”), high density and high integration by miniaturization and lamination of wiring have been required for size reduction and high speed. Various techniques such as chemical mechanical polishing (hereinafter referred to as “CMP”) have been used for this purpose. CMP is an essential technique when performing surface leveling of a film to be subjected to processing such as an interlayer insulating film, plug formation, formation of embedded metal wire, or the like, and is used to perform leveling of a substrate, removal of excess metal thin film at the time of wiring formation and removal of excess barrier layer from an insulating film.

The general method of CMP is such that a polishing pad is adhered to a circular polishing platen, the surface of the polishing pad is immersed with a polishing liquid, the surface of a substrate (wafer) is pressed against the pad, both the polishing platen and the substrate are rotated in a state of application of predetermined pressure (polishing pressure) from the back sides thereof, and the surface of the substrate is leveled by the mechanical friction generated.

In the production of semiconductor devices such as LSI, fine wirings are formed in multiple layers. In the formation of metal wiring with, for example, Cu in respective layers, a barrier metal such as Ta, TaN, Ti, TiN or the like is formed in advance for the purpose of preventing diffusion of a wiring material into an interlayer insulating film, and improving the adhesion of the wiring material.

To form each wiring layer, it is generally the case that CMP of a metal film (hereinafter referred to as “metal film CMP”) for removing excess wiring material formed by a plating method or the like is conducted first in one stage or plural stages, and then CMP for removing a barrier metal material (barrier metal) exposed on the surface (hereinafter referred to as “barrier metal CMP”) is conducted. However, a problem known as dishing may occur, whereby the wiring portion is overpolished by metal film CMP and, additionally, erosion may be caused.

To reduce dishing, it is required that in the barrier metal CMP conducted subsequent to the metal film CMP, the polishing rate of a metal wiring portion and the polishing rate of a barrier metal portion are adjusted so as to ultimately form a wiring material having reduced unevenness (difference in level) such as that caused by dishing or erosion. In other words, in the barrier metal CMP, when the polishing rate of a barrier metal or an interlayer insulating layer is relatively low as compared with in the case of a metal wiring material, dishing, whereby a wiring portion is quickly polished, and erosion as a result thereof, are generated. Therefore, it is necessary that the polishing rate of a barrier metal or an interlayer insulating film is adequately high. In addition to the merit of increasing the throughput of barrier metal CMP, this is also desirable in terms of the fact that in practice dishing is frequently generated by metal film CMP, and a relative increase in the polishing rate of a barrier metal or an interlayer insulating film has been demanded for the reasons described above.

A metal polishing liquid used for CMP generally contains abrasive grains (such as alumina and silica) and an oxidizing agent (such as hydrogen peroxide or persulfuric acid). The basic mechanism is thought to involve a metal surface being oxidized with an oxidizing agent, and the resulting oxide coating being removed with abrasive grains, thereby performing polishing.

However, when CMP is conducted using a polishing liquid containing these solid abrasive grains, damage caused by polishing (scratches), or phenomena such as excessive polishing (thinning) of the whole polished surface, excessive polishing of a part of a metal surface subjected to polishing resulting in depression of the surface in a dish form (dishing), or excessive polishing of an insulating material between metal wirings together with deep polishing of only a central portion of plural wiring metal surfaces, resulting in depression of the surface in a dish form (erosion), and the like may occur.

Furthermore, when a polishing liquid containing solid abrasive grains is used, issues of cost are raised in that a cleaning step that is generally conducted to remove residual polishing liquid from a semiconductor surface after polishing becomes more complex and, additionally, precipitation separation of solid abrasive grains is necessary for disposal of the liquid (waste liquid) after polishing.

The following variety of studies have been conducted on polishing liquids containing solid abrasive grains.

For example, a CMP abrasive agent and a polishing method intended to perform rapid polishing substantially without generating polishing damage (for example, see Japanese Patent Application Laid-Open (JP-A) No. 2003-17446), an abrasive composition and a polishing method having improved cleaning properties in CMP (for example, see JP-A No. 2003-142435), and a polishing composition intended to prevent agglomeration of polishing abrasive grains (for example, see JP-A No. 2000-84832) have been proposed.

However, the current situation is that even with the above polishing liquids, a technique that can realize a high polishing rate for polishing a target layer and that can suppress scratches generated due to agglomeration of solid abrasive grains, has not yet been obtained.

In particular, recently, in conjunction with further miniaturization of wiring, a low dielectric material having a dielectric constant lower than that of an interlayer insulating film that is generally used such as tetraethoxysilane (TEOS), has been used as an insulating film. These insulating films are known as Low-k film, and examples thereof include film made of, for example, organic polymer, SiOC or SiOF materials. These Low-k films are generally used by lamination together with an insulating film. However, Low-k films are not as strong as conventional insulating films and the above-described problems of excessive polishing and scratches become yet further pronounced in CPM processing.

### SUMMARY OF THE INVENTION

In view of the above circumstances, the present invention has been made and provides a polishing liquid and a polishing method.

According to an aspect of the invention, there is provided a polishing liquid for polishing a barrier layer of a semiconductor integrated circuit. The polishing liquid includes surface modified particles that include organic polymer particles having at least one inorganic atom selected from the group consisting of Ti, Al, Zr and Si bonded to the organic polymer particles via an oxygen atom that is present on a surface of the organic polymer particles, an organic acid, an azole compound having at least two carboxyl groups, and an oxidizing agent. The polishing liquid has a pH of from 1 to 7.

According another aspect of the invention, there is provided a polishing method for polishing a barrier layer of a semiconductor integrated circuit The polishing method includes supplying, to a polishing pad on a polishing platen a polishing liquid; and contacting a surface to be polished of a material to be polished with the polishing pad and subjecting the surface to be polished and the polishing pad to relative motion. The polishing liquid includes surface modified particles that include organic polymer particles having at least one inorganic atom selected from the group consisting of Ti, Al, Zr and Si bonded to the organic polymer particles via an oxygen atom present on a surface of the organic polymer particles, an organic acid, an azole compound having at least two carboxyl groups, and an oxidizing agent. The polishing liquid has a pH of from 1 to 7.

### DETAILED DESCRIPTION OF THE INVENTION

The specific embodiments of the present invention will be described below.

The polishing liquid of the invention is used for chemical and mechanical polishing of mainly a barrier layer in the leveling process in a manufacturing process for a semiconductor integrated circuit. The polishing liquid of the invention includes (1) surface modified particles that includes organic polymer particles having at least one inorganic atom selected from the group consisting of Ti, Al, Zr and Si bonded to the organic polymer particles via an oxygen atom present on a surface of the organic polymer particles, (2) an organic acid, (3) an azole compound having at least two carboxyl groups, and (4) an oxidizing agent. The polishing liquid has a pH of from 1 to 7. The polishing liquid may further include any additional components, according to need.

Each component contained in the polishing liquid of the invention may be used alone or a mixture of two or more kinds thereof.

The meaning of the “polishing liquid” in the invention includes not only a polishing liquid when used in polishing (that is, a polishing liquid diluted according to need), but also a concentrated liquid of a polishing liquid. The concentrated liquid or the concentrated polishing liquid means a polishing liquid adjusted to have a solute concentration higher than that of a polishing liquid when used in polishing, and is diluted with water or an aqueous solution when used in polishing, and used for polishing. Dilution ratio is generally from 1 to 20 times by volume. The “concentration” and “concentrated liquid” used herein are used according to custom expression that means “denseness” and “dense liquid” rather than use state, and are used in the usage different from the general terms involving physical concentration operation such as evaporation.

Each component constituting the polishing liquid of the invention is described in detail below.

(1) Surface Modified Particles

The “surface modified particles” are particles comprising including polymer particles having at least one inorganic atom selected from the group consisting of Ti, Al, Zr and Si (hereinafter sometimes referred to as “specific inorganic atom”) bonded to the organic polymer particles through an oxygen atom on that is present a surface of the organic polymer particles.

Thus, by modifying the surface of the organic polymer particles with the specific inorganic atom, the surface of the organic polymer particles has sufficient strength and hardness, is excellent in heat resistance, and is appropriately flexible. As a result, when the organic polymer particles are used as abrasive grains, polishing rate can be increased and additionally generation of scratches can be suppressed.

Organic Polymer Particles

As the organic polymer particles, for example, polymer particles of thermoplastic resins such as polystyrene; styrene copolymer; (meth)acrylic resin such as polymethyl methacrylate; acrylic copolymer; polyvinyl chloride; polyacetal; saturated polyester; polyamide; polyimide; polycarbonate; phenoxy resin; polyolefin such as polyethylene, polypropylene, poly-1-butene or poly-4-methyl-1-pentene; or olefin copolymer, may be used.

Further, as the polymer particles, particles of a polymer having a crosslinked structure, obtained by copolymerizing styrene, methyl methacrylate or the like with divinyl benzene, ethylene glycol dimethacrylate or the like, may be used. Furthermore, polymer particles of a thermosetting resin such as phenol resin, urethane resin, urea resin, melamine resin, epoxy resin, alkyd resin or unsaturated polyester resin may be used.

A functional group such as a hydroxyl group, an epoxy group or a carboxyl group may be introduced into the organic polymer particles. When the functional group is introduced into the organic polymer particles, the specific inorganic atom may be bonded to the organic polymer particles through such a functional group without using a connecting compound such as a silane coupling agent.

As described hereinafter, when a silane coupling agent having a functional group capable of reacting with the functional groups introduced is used together for bonding the specific inorganic atom and the organic polymer particles, the bonding between the specific inorganic atom and the organic polymer particles is further accelerated, and composite particles having further excellent performance can be obtained.

The organic polymer particles may be obtained by polymerizing a monomer(s) any of by various methods such as emulsion polymerization, suspension polymerization and dispersion polymerization. According to those polymerization methods, a particle size of the organic polymer particles can appropriately be adjusted depending on polymerization conditions and the like. Furthermore, a polymer in bulk form or the like may be pulverized to form organic polymer particles having the necessary particle size. In particular, when organic polymer particles having large strength and excellent heat resistance are required, a polyfunctional monomer may additionally be used to introduce a crosslinked structure in the molecule in producing the organic polymer particles. The crosslinked structure may be introduced by methods such as chemical crosslinking or electron beam crosslinking in the course of the production of the organic polymer particles or after the production of the organic polymer particles.

As the organic polymer particles, besides the particles as described above, particles of any of various polymers such as polyamide, polyester, polycarbonate and polyolefin, may also be used. In those organic polymer particles, a functional group may be introduced therein as same as above, and furthermore, a crosslinked structure may be introduced into the molecule.

Of the above organic polymer particles, from the points of TEOS polishing rate and scratch performance after polishing, polyvinyl chloride, polyacetal, saturated polyester, polyamide, polyimide, polycarbonate, phenoxy resin, polyethylene, polypropylene polymethyl methacrylate particles, polystyrene polymer particles, divinylbenzene polymer particles, styrene-divinylbenzene copolymer particles, styrene-methacrylic acid copolymer particles and acrylic acid-methyl methacrylate copolymer particles are preferred, and polymethyl methacrylate particles, polystyrene polymer particles, divinylbenzene polymer particles, styrene-divinylbenzene copolymer particles, styrene-methacrylic acid copolymer particles and acrylic acid-methyl methacrylate copolymer particles are more preferred.

Bonding between Organic Polymer Particles and Specific Inorganic Atom

Organic polymer particles and specific inorganic atom are chemically or non-chemically bonded through oxygen atom, but those are preferably bonded by a chemical bond. This can prevent that the specific inorganic atom is easily separated from the organic polymer particles during polishing, thereby decreasing TEOS polishing effect and scratch performance. The chemical bond includes an ion bond and a coordinate bond, but a covalent bond is more preferred that the organic polymer particles and the specific inorganic atom are particularly strongly bonded. The non-chemical bond includes a hydrogen bond and a surface charge bond.

The bond between the organic polymer particles and the inorganic atom may include a “portion containing a metalloxane bond and the like (hereinafter, may be referred to as a metalloxane bond and the like-containing portion)” and/or an “inorganic particle portion”, or may include at least two kinds of those. Examples of the “metalloxane bond and the like-containing portion” include a portion containing a siloxane bond which is one of bonds between the organic polymer particles and Si atom (siloxane bond-containing portion) and a portion containing a metalloxane bond which is one of bonds between the organic polymer particles and Al atom, Ti atom or Zr atom (metalloxane bond-containing portion). Examples of the “inorganic particle moiety” include a silica particle portion, an alumina particle portion, a titania particle portion or a zirconia particle portion.

The bond between the organic polymer particles and the inorganic atom may be formed in the inside of or over the entire surface of the organic polymer particles or may be formed on a part thereof, so long as it is a bond formed through oxygen atom. The metalloxane bond and the like-containing portion, such as a siloxane bond-containing portion and the like, may be constituted of a single molecule, but a chain structure of two molecules or more is preferred. In the case of a chain structure, it may be a linear structure, but a three-dimensional structure is more preferred.

The introduction of the metalloxane bond and the like-containing portion and/or the inorganic particle portion onto the surface of the organic polymer particles may be conducted by bonding through a connecting compound such as a coupling agent.

As the coupling agent, any of coupling agents such as a silane coupling agent, an aluminum coupling agent, a titanium coupling agent and a zirconium coupling agent, may be used. Of those, a silane coupling agent is particularly preferred.

Examples of the preferred silane coupling agent include vinyltrichlorosilane, vinyltris(13-methoxyethoxy)silane, vinyltriethoxysilane, vinyltrimethoxysilane, β(3,4-epoxycyclohexyl)ethyltrimethoxysilane, γ-glycidoxypropyltrimethoxysilane, γ-glycidoxypropyl diethoxysilane, N-β(aminoethyl)γ-aminopropyltrimethoxysilane, N-β(aminoethyl)γ-aminopropylmethyldimethoxysilane, N-β(N-vinylbenzylaminoethyl)-γ-aminopropyltrimethoxysilane, γ-aminopropyltriethoxysilane, N-phenyl-γ-aminopropyltrimethoxysilane, γ-mercaptopropyltrimethoxysilane, γ-chloropropyltrimethoxysilane, 3-methacryloxypropyltrimethoxysilane, 4-glycidylbutyltrimethoxysilane, N-3-(4-(3-aminopropoxy)butoxy)propyl-3-aminopropyltrimethoxysilane, 3-mercaptopropyltrimethoxysilane, imidazole silane and triazinesilane.

Of those silane coupling agents, compounds having in the molecule thereof a functional group capable of easily reacting with the functional groups such as hydroxyl group, epoxy group or carboxyl group introduced into the organic polymer particles are preferred. For example, in the case of organic polymer particles having a carboxyl group introduced onto the surface thereof, silane coupling agents having an epoxy group or an amino group, such as γ-glycidoxypropyltrimethoxysilane, γ-glycidoxypropylmethyl diethoxysilane, N-β(aminoethyl)γ-aminopropyltrimethoxysilane, N-β(aminoethyl)γ-aminopropylmethyldimethoxysilane, γ-aminopropyltriethoxysilane are preferred. Of those, γ-glycidoxypropyltrimethoxysilane and N-β(aminoethyl)γ-aminopropyltrimethoxysilane are particularly preferred.

Examples of the aluminum coupling agents include acetoalkoxyaluminum diisopropylate. The titanium coupling agent includes isopropyltriisostearoyl titanate, isopropyltridecylbenzenesulfonyl titanate, isopropyltricumylphenyl titanate, PLENACT KR, TTS, KR 46B, KR 55, KR 41B, KR 38S, KR 138S, KR238S, 338X, KR 44, KR 9SA and the like. Those various coupling agents may be used alone or as mixtures of two or more thereof. Furthermore, coupling agents of different kinds may be used together.

Specific Inorganic Atom-Containing Compound

The following compounds may be used as a compound for introducing the metalloxane bond-containing portion and/or the inorganic particle portion onto the surface of the organic polymer particles (hereinafter may be referred to as a “specific inorganic atom-containing compound”).

Examples of the compounds containing a Si atom include tetramethoxysilane, tetraethoxysilane, tetra-iso-propoxysilane, tetra-tert-butoxysilane, methyl trimethoxysilane and methyl triethoxysilane. A siloxane bond-containing portion and a silica particle portion are formed from those compounds. Examples of the compound containing Al atom include aluminum ethoxide. Examples of the compound containing Ti atom include titanium (IV) ethoxide. Examples of the compound containing Zr atom include zirconium-tert-butoxide. A metalloxane bond-containing portion and an alumina particle portion, a titania particle portion or a zirconia particle portion are formed from those compounds. Those compounds may be used alone or as mixtures of two or more thereof.

Of the above specific inorganic atom-containing compounds, the compound containing Si atom, the compound containing Al atom or the compound containing Ti atom is preferred from the points of TEOS polishing rate and scratch performance after polishing, and the compound containing Si atom or the compound containing Al atom is more preferred.

The surface modified particles in the invention are preferably organic polymer particles having Si atom or Al atom bonded thereto through oxygen atom on the surface thereof. The preferred combination of the organic polymer particles and the specific inorganic atom-containing compound is a combination of divinylbenzene polymer particles and the compound containing Si atom, a combination of divinylbenzene polymer particles and the compound containing Al atom, and a combination of acrylic acid-methyl methacrylate copolymer particles and the compound containing Si atom.

Above all, the organic polymer particles having Si atom bonded thereto through oxygen atom on the surface thereof are more preferred. The more preferred combination of the organic polymer particles and the specific atom-containing compound is a combination of divinylbenzene polymer particles and the compound containing Si atom, and a combination of acrylic acid-methyl methacrylate copolymer particles and the compound containing Si atom.

The amount of the specific inorganic atom is preferably from 0.01 to 100% by mass, and more preferably from 0.1 to 50% by mass, based on the organic polymer particles from the viewpoint of TEOS polishing rate.

The amount of the specific inorganic atom-containing compound is preferably from 0.01 to 50% by mass, and more preferably from 0.01 to 10% by mass, based on the organic polymer particles from the viewpoint of suppression of scratch.

Properties of Surface Modified Particles

The surface modified particles preferably have a primary average particle size in a range of from 20 to 150 nm. When the primary average particle size of the surface modified particles is 20 nm or more, TEOS polishing rate is sufficiently large, and when it is 150 nm or less, it is effective to reduce scratches after polishing.

The “primary average particle size” used herein means a value obtained by observing the surface modified particles with SEM (scanning electron microscope) and measuring the minimum constituent particle size constituting one particle.

The concentration of the surface modified particles is preferably from 0.5 to 15% by mass, and more preferably from 0.5 to 10% by mass, based on the total mass of the polishing liquid.

When the concentration of the surface modified particles is 0.5% by mass or more based on the total mass of the polishing liquid, TEOS polishing rate is sufficient, and when it is 15% by mass or less, it is effective to reduce scratches after polishing.

Other Abrasive Grains

Other than the above surface modified particles, abrasive grains generally used may be used together. Examples of the abrasive grain include silica (precipitated silica, fumed silica, colloidal silica and synthetic silica), ceria, alumina, titania, zirconia, germania, manganese oxide, silicon carbide, polystyrene, polyacryl and polyterephthalate.

The abrasive grain has an average particle size of preferably from 5 to 1,000 nm, and particularly preferably from 10 to 200 nm.

When the abrasive grains are used, the addition amount thereof is such that the total amount of the abrasive grains and the surface modified particles is in a range of preferably from 0.01 to 20% by mass and more preferably 0.05 to 5% by mass, based on the total mass of the polishing liquid when used. The amount of 0.01% by mass or more is preferred for obtaining improvement of the polishing rate and sufficient effect in reducing variation of the polishing rate on a wafer plane, and the amount of 20% by mass or less is preferred in view of the saturation of the polishing rate in CMP.

(2) Organic Acid

The polishing liquid of the invention further contains an organic acid.

The organic acid used herein is a compound having a structure different from an oxidizing agent for oxidizing a metal, and does not encompass an acid which functions as an oxidizing agent described later. The acid used herein has the function to promote oxidization, to adjust pH and to act as a buffer.

At least one selected from the group consisting of an oxalic acid, a citric acid, a lactic acid, a malonic acid, a succinic acid, a glutaric acid, an adipic acid, a maleic acid, a malic acid, a tartaric acid and their derivatives is more suitable as the organic acid in the invention.

Of those, a malic acid, a tartaric acid and a citric acid are particularly preferred since it is possible to effectively suppress an etching rate while maintaining a practical CMP rate.

The organic acid is added in an amount of preferably from 0.0005 to 0.5 mol, more preferably from 0.005 to 0.3 mol, and particularly preferably from 0.01 to 0.1 mol, to 1 liter of the polishing liquid when used for polishing. That is, the addition amount of the organic acid is preferably 0.5 mol or less from the viewpoint of suppression of etching, and is preferably 0.0005 mol or more from the viewpoint of obtaining sufficient effect.

(3) Azole Compound Having at Least Two Carboxyl Groups

The polishing liquid of the invention contains an azole compound having at least two carboxyl groups. This compound functions as a corrosion inhibitor in the polishing liquid.

When the polishing liquid contains the azole compound having at least two carboxyl groups (hereinafter referred to as a “specific azole compound”), dishing can be suppressed, and when the specific azole compound is used together with the surface modified particles described in (1) above, residue after polishing can be reduced, which is particularly excellent in suppression of corrosion.

The specific azole compound has preferably 2 to 5 carboxyl groups, and more preferably 2 to 4 carboxyl groups, from the viewpoint of reducing residue after polishing. When the carboxyl group is only one, corrosion suppression ability is insufficient.

The specific azole compound is preferably a compound represented by the following formula (I) or formula (II).

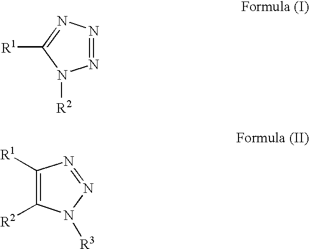

In formula (I), R¹ and R² each independently represent a hydrogen atom, a carboxyl group, a carboxyalkyl group or a carboxyaryl group, and in formula (II), R¹, R² and R³ each independently represent a hydrogen atom, a carboxyl group, a carboxyalkyl group or carboxyaryl group. The compounds represented by the above formula (I) and formula (II) have at least two carboxyl groups in the molecule.

Specific examples of the specific azole compound represented by formula (I) include 1-carboxymethyl-1H-tetrazole-5-carboxylic acid, 1-(2-carboxyphenyl)-1H-tetrazole-5-carboxylic acid, 1-(4-carboxyphenyl)-1H-tetrazole-5-carboxylic acid, 2-(1H-tetrazole-5-yl)succinic acid, and 3-(1-(carboxymethyl)-1H-tetrazole-5-yl)propanoic acid.

Specific examples of the specific azole compound represented by formula (II) include 1H-1,2,3-triazole-4,5-dicarboxylic acid, 1-(carboxymethyl)-1H-1,2,3-triazole-4,5-dicarboxylic acid, 1-(2-carboxymethyl)-1H-1,2,3-triazole-4,5-dicarboxylic acid, 5-(carboxymethyl)-3H-1,2,3-triazole-4-carboxylic acid, 2-(1H-1,2,3-triazole-4-yl)succinic acid, 1-(carboxymethyl)-1H-1,2,3-triazole-4-carboxylic acid, 1-(1-carboxymethyl)-1H-1,2,3-triazole-4-carboxylic acid, and 2-(1-H-1,2,3-triazole-1-yl)succinic acid.

Specific examples of the specific azole compound represented by formula (I) or formula (II) further include the following compounds. However, the specific azole compound in the invention is not limited to the following specific examples.

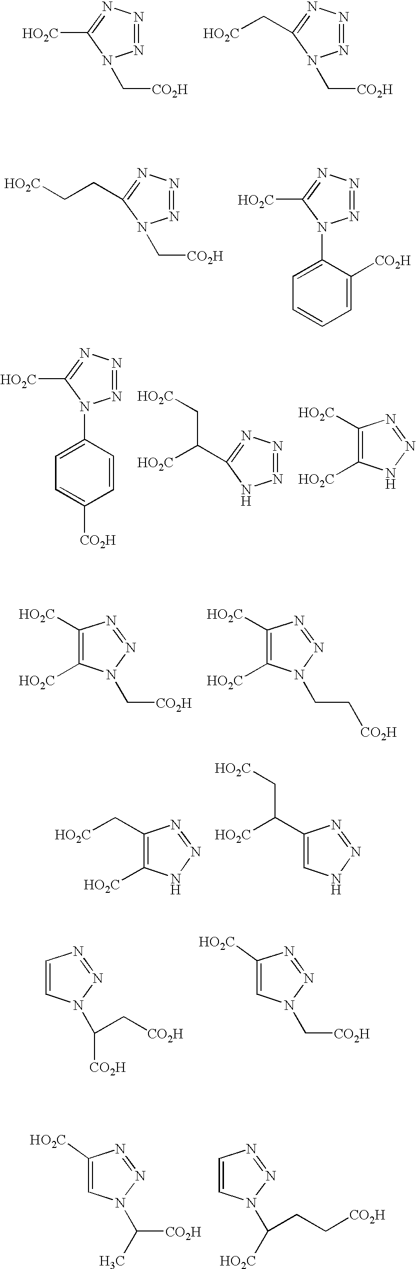

Of the above specific azole compounds, 1-carboxymethyl-1H-tetrazole-5-carboxylic acid, 1-(2-carboxyphenyl)-1H-tetrazole-5-carboxylic acid, 1-(4-carboxyphenyl)-1H-tetrazole-5-carboxylic acid, 2-(1H-tetrazole-5-yl)succinic acid, 1H-1,2,3-triazole-4,5-dicarboxylic acid, 1-(carboxymethyl)-1H-1,2,3-triazole-4,5-dicarboxylic acid, 1-(2-carboxymethyl)-1H-1,2,3-triazole-4,5-dicarboxylic acid, 5-(carboxymethyl)-3H-1,2,3-triazole-4-carboxylic acid, and 2-(1H-1,2,3-triazole-4-yl)succinic acid are preferred from the viewpoints of suppressing dishing and reducing residue after polishing, and 1-(2-carboxyphenyl-1H-tetrazole-5-carboxylic acid, 1-(4-carboxyphenyl)-1H-tetrazole-5-carboxylic acid, 2-(1H-tetrazole-5-yl)succinic acid, 1H-1,2,3-triazole-4,5-dicarboxylic acid and 1-(carboxymethyl)-1H-1,2,3-triazole-4,5-dicarboxylic acid are more preferred.

Those specific azole compounds may be used alone or as mixtures of two or more thereof.

In the invention, the specific azole compound is added in an amount in a range of preferably from 0.01 to 2% by mass, more preferably from 0.05 to 1% by mass, and still more preferably from 0.05 to 0.5% by mass, based the polishing liquid when used in polishing.

Other Corrosion Inhibitors

The polishing liquid of the invention may contain a heterocyclic compound that is generally used as a corrosion inhibitor, in addition to the above specific azole compound.

The term “heterocyclic compound” used herein means a compound having a heterocycle containing at least one hetero atom. The term “hetero atom” used herein means an atom other than carbon atom or hydrogen atom. The term “heterocycle” used herein means a cyclic compound having at least one hetero atom. The hetero atom means only an atom forming a portion constituting a ring system of a heterocycle, and does not mean an atom which is positioned outside the ring system, is separated from the ring system by at least one non-conjugated single bond, and is a part of further substituent of the ring system.

As the hetero atom, a nitrogen atom, a sulfur atom, an oxygen atom, a selenium atom, a tellurium atom, a phosphor atom, a silicon atom and a boron atom are preferable; a nitrogen atom, a sulfur atom, an oxygen atom and a selenium atom are more preferable; a nitrogen atom, a sulfur atom and an oxygen atom are still more preferable; and a nitrogen atom and a sulfur atom are most preferable.

Regarding a heterocycle as a mother nucleus, the number of ring and the number of member of ring of the heterocycle in a heterocyclic compound is not particularly limited, and the compound may be a monocyclic compound or a polycyclic compound having a condensed ring. The number of a ring member in the case of a monocycle is preferably from 5 to 7, and particularly preferably 5. The number of ring in the case having a condensed ring is preferably 2 or 3.

Specific examples of those heterocycles are described below, but the invention is not limited to those.

That is, the specific examples of the heterocycles include a pyrrole ring, a thiophene ring, a furan ring, a pyrane ring, a thiopyrane ring, an imidazole ring, a pyrazole ring, a thiazole ring, an isothiazole ring, an oxazole ring, an isooxazole ring, a pyridine ring, a pyradine ring, a pyrimidine ring, a pyridazine ring, a pyrrolidine ring, a pyrrazoline ring, an imidazoline ring, an isooxazoline ring, an isothiazoline ring, a piperidine ring, a piperadine ring, a morpholine ring, a thiomorpholine ring, a chroman ring, a thiochroman ring, an isochroman ring, an isothiochroman ring, an indoline ring, an isoindoline ring, a pyrindine ring, an indolidine ring, an indole ring, an indazole ring, a purine ring, a quinolidine ring, an isoquinoline ring, a quinoline ring, a naphthylidine ring, a phthaladine ring, a quinoxaline ring, a quinazoline ring, a cinnoline ring, a pteridine ring, an acridine ring, a perimidine ring, a phenanthroline ring, a carbazole ring, a carboline ring, a phenazine ring, an anthyridine ring, a thiadiazole ring, an oxadiazole ring, a triazine ring, a triazole ring, a tetrazole ring, a benzimidazole ring, a benzoxazole ring, a benzthiadiazole ring, a benzfroxan ring, a naphthoimidazole ring, a benztriazole ring, a tetraazaindene ring, and the like. A triazole ring and a tetrazole ring are more preferred.

Substituents that the above heterocycle may have are described below.

Examples of the substituent that may be introduced into the heterocycle are as follows. However, the invention is not limited to those.

That is, the examples of the substituents include a halogen atom, an alkyl group (a linear, branched or cyclic alkyl group; the alkyl group may be a polycyclic alkyl group such as a bicycloalkyl group; the alkyl group may contain an active methine group), an alkenyl group, an alkynyl group, an aryl group, an amino group and a heterocyclic group.

Two or more of plural substituents may be bonded to form a ring. For example, an aromatic ring, an aliphatic hydrocarbon ring, heterocyclic ring or the like may be formed, and those may be further combined to form a polycyclic condensed ring. Specific examples of the ring formed include a benzene ring, a naphthalene ring, an anthracene ring, a pyrrole ring, a furan ring, a thiophene ring, an imidazole ring, an oxazole ring and a thiazole ring.

Specific examples of the heterocyclic compound that may be preferably used in the invention include the following compounds, but the invention is not limited to those.

That is the specific examples of the heterocyclic compound include 1,2,3,4-Tetrazole, 5-amino-1,2,3,4-tetrazole, 5-methyl-1,2,3,4-tetrazole, 1,2,3-triazole, 4-amino-1,2,3-triazole, 4,5-diamino-1,2,3-triazole, 1,2,4-triazole, 3-amino-1,2,4-triazole, 3,5-diamino-1,2,4-triazole, a benzotriazole and the like.

The heterocyclic compound is more preferably a benzotriazole or a derivative thereof. The derivative of a benzotriazole is preferably 5,6-dimethyl-1,2,3-benzotriazole (DBTA), 1-[N,N-bis(hydroxyethyl)aminomethyl]benzotriazole (HEABTA) and 1-(hydroxymethyl)benzotriazole (HMBTA).

The heterocyclic compound may be used alone or as mixtures of two or more thereof.

In the invention, the heterocyclic compound may be added in an amount so as to obtain the total amount of the specific azole compound and the heterocyclic compound in a range of preferably from 0.01 to 2% by mass, more preferably from 0.05 to 1% by mass, and still more preferably from 0.05 to 0.5% by mass, based on the polishing liquid when used in polishing.

(4) Oxidizing Agent

The polishing liquid of the invention contains a compound (oxidizing agent) that can oxidize a metal to be polished. Examples of the oxidizing agent include hydrogen peroxide, a peroxide, a nitrate, an iodate, a periodate, a hypochlorite, a chlorite, a chlorate, a perchlorate, a persulfate, a bichromate, a permanganate, an ozone water, a silver (II) salt and an iron (III) salt. Of those, hydrogen peroxide is preferably used.

As the iron (III) salt, for example, an inorganic iron (III) salts such as iron (III) nitrate, iron (III) chloride, iron (III) sulfate, iron (III) bromide may be preferable used. Further, an organic complex salt of iron (III) may be preferably used.

The amount of the oxidizing agent added can be adjusted by a dishing amount at the initial stage of barrier CMP. When the dishing amount at the initial stage of barrier CMP is large, that is, when it is not desired to polish a wiring material too much in barrier CMP, it is desirable that the oxidizing agent is added in small amount. When the dishing amount is sufficiently small and it is desired to polish a wiring material at high rate, it is desirble that the oxidizing agent is added in large amount. Thus, it is desirable to vary the amount of the oxidizing agent added depending on the dishing state at the initial stage of barrier CMP, and therefore, the amount of the oxidizing agent is preferably from 0.01 to 1 mol, and particularly preferably from 0.05 to 0.6 mol, in 1 liter of the polishing liquid when used in polishing.

Other Components

The polishing liquid of the invention may further contain other conventional components in a range that the effect of the invention is not impaired, in addition to each component shown by (1) to (4) as the essential components, other abrasive grains that can optionally be used, and other corrosion inhibitors.

Surfactant and/or Hydrophilic Polymer

The metal polishing liquid of the invention preferably contains a surfactant and/or a hydrophilic polymer. The surfactant and the hydrophilic polymer each have a function to decrease a contact angle of a surface to be polished, and therefore have a function to promote uniform polishing. The surfactant and/or the hydrophilic polymer that may be used are preferably selected from the following anionic surfactants, cationic surfactants, amphoteric surfactant, nonionic surfactant, fluorine surfactants, other surfactant, hydrophilic compound, hydrophilic polymer and the like.

Examples of the anionic surfactants include a carboxylate, a sulfonate, a sulfuric ester salt and a phosphoric ester salt. More specifically, examples of the carboxylate include a soap, a N-acylamino acid salt, a polyoxyethylene alkyl ether carboxylate, polyoxypropylene alkyl ether carboxylate and acylated peptide; examples of the sulfonate include an alkyl sulfonate, an alkyl benzene and an alkyl naphthalene sulfonate, a naphthalene sulfonate, a sulfosuccinate, an α-olefin sulfonate and an N-acylsulfonate; examples of the sulfuric ester salt include a sulfated oil, an alkyl sulfate, an alkyl ether sulfate, a polyoxyethylene alkyl allyl ether sulfate, polyoxypropylene alkyl allyl ether sulfate and alkyl amide sulfate; and examples of the phosphate include alkyl phosphate, and polyoxyethylene alkyl allyl ether sulfate and polyoxypropylene alkyl allyl ether phosphate.

Examples of the cationic surfactants include an aliphatic amine salt, an aliphatic quaternary ammonium salt, a benzalkonium chloride salt, a benzetonium chloride,a pyridinium salt and an indazolinium salt.

Examples of the amphoteric surfactants include a carboxybetaine type amphoteric surfactant, an aminocarboxylate, an imidazolinium betaine, a lecithin and an alkyl amine oxide.

Examples of the nonionic surfactants include an ether type nonionic surfactant, an ether ester type nonionic surfactant, an ester type nonionic surfactant and a nitrogen-containing type nonionic surfactant. More specifically, examples of the ether type nonionic surfactants include a polyoxyethylene alkyl and alkyl phenyl ether, an alkyl allyl formaldehyde condensed polyoxyethylene ether, a polyoxyethylene polyoxypropylene block copolymer and a polyoxyethylene polyoxypropylene alkyl ether; examples of the ether ester type nonionic surfactants include polyoxyethylene ether of glycerin ester, polyoxyethylene ether of sorbitan ester and polyoxyethylene ether of sorbitol ester; examples of the ester type nonionic surfactants include polyethylene glycol fatty acid ester, glycerin ester, polyglycerin ester, sorbitan ester, propylene glycol ester and sucrose ester; and examples of the nitrogen-containing type nonionic surfactants include a fatty acid alkanol amide, a polyoxyethylene fatty acid amide and a polyoxyethylene alkyl amide.

Furthermore, a fluorine surfactant may be used.

Examples of other surfactants, hydrophilic compounds, hydrophilic polymers and the like include esters such as glycerin ester, sorbitan ester, methoxyacetic acid, ethoxyacetic acid, 3-ethoxypropionic acid and alanine ethyl ester; ethers such as polyethylene glycol, polypropylene glycol, polytetramethylene glycol, a polyethylene glycol alkyl ether, a polyethylene glycol alkenyl ether, an alkyl polyethylene glycol, an alkyl polyethylene glycol alkyl ether, an alkyl polyethylene glycol alkenyl ether, an alkenyl polyethylene glycol, an alkenyl polyethylene glycol alkyl ether, an alkenyl polyethylene glycol alkenyl ether, an polypropylene glycol alkyl ether, a polypropylene glycol alkenyl ether, an alkyl polypropylene glycol, an alkyl polypropylene glycol alkyl ether, an alkyl polypropylene glycol alkenyl ether, an alkenyl polypropylene glycol, an alkenyl polypropylene glycol alkyl ether and an alkenyl polypropylene glycol alkenyl ether; polysuccharides such as alginic acid, pectinic acid, carboxymethyl cellulose, curdlan and pullulan; amino acid salts such as glycine ammonium salt and glycine sodium salt; polycarboxylic acids and salts thereof, such as polyasparaginic acid, polyglutamic acid, polylycine, polymalic acid, polymethacrylic acid, polymethacrylic ammonium salt, polymethacrylic sodium salt, polyamide acid, polymaleic acid, polyitaconic acid, polyfumaric acid, poly(p-styrenecarboxylic acid), polyacrylic acid, polyacrylamide, aminopolyacrylamide, polyacrylic ammonium salt, polyacrylic sodium salt, polyamic acid, polyamic ammonium salt, polyamic sodium salt and polyglyoxylic acid; vinyl polymers such as polyvinyl alcohol, polyvinyl pyrrolidone and polyacrolein; sulfonic acids and salts thereof, such as methyltauric ammonium salt, methyltauric sodium salt, methyl sulfate sodium salt, ethyl sulfate ammonium salt, butyl sulfate ammonium salt, vinylsulfonic sodium salt, an 1-allylsulfonic acid sodium salt, an 2-allylsulfonic acid sodium salt, methoxymethylsulfonic sodium salt, ethoxymethylsulfonic ammonium salt, 3-ethoxypropylsulfonic sodium salt, methoxymethylsulfonic sodium salt, ethoxymethylsulfonic ammonium salt, 3-ethoxypropylsulfonic sodium salt and sulfosuccinic sodium salt; and amides such as propion amide, acrylamide, methyl urea, nicotinamide, succinic acid amide and sulfanilamide.

When a substrate applied is, for example, a silicon substrate for a semiconductor integrated circuit, contamination with an alkali metal, an alkaline earth metal, a halide or the like is not desired, and therefore, an acid or its ammonium salt is desired. When the substrate is, for example, a glass substrate, the above is not applied. Of the compounds described above, cyclohexanol, polyacrylic ammonium salt, polyvinyl alcohol, succinic acid amide, polyvinylpyrrolidone, polyethylene glycol and a polyoxyethylene polyoxypropylene block copolymer are more preferred.

The surfactant and/or the hydrophilic polymer are added in an amount of from 0.001 to 10 g, more preferably from 0.01 to 5 g, and particularly preferably from 0.1 to 3 g, in terms of the total amount thereof, in 1 liter of a metal polishing liquid (use solution) when used in polishing. Specifically, the amount of the surfactant and/or the hydrophilic polymer added is preferably 0.001 g more in obtaining sufficient effect, and is preferably 10 g or less from the viewpoint of preventing decrease of CMP rate. Furthermore, the surfactant and/or the hydrophilic polymer have a weight average molecular weight of preferably from 500 to 100,000, and particularly preferably from 2,000 to 50,000.

pH Adjuster

The polishing liquid of the invention is required to have a pH of from 1 to 7, and preferably has a pH in a range of from 3.0 to 4.5. By controlling pH of the polishing liquid to from 1 to 7, it is possible to conduct polishing rate adjustment of an interlayer insulating film further remarkably.

An alkali/acid or a buffer may appropriately be used to adjust the pH in the above range. The polishing liquid of the invention exhibits excellent effect when pH is fallen within the above range.

Preferable examples of the alkali/acid or the buffer include non-metal alkaline chemicals, for example, organic ammonium hydroxides such as ammonia, ammonium hydroxide and tetramethylammonium hydroxide; alkanol amines such as diethanol amine, triethanol amine and triisopropanol amine; alkali metal hydroxides such as sodium hydroxide, potassium hydroxide or lithium hydroxide; inorganic acids such as nitric acid, sulfuric acid or phosphoric acid; carbonates such as sodium carbonate; phosphates such as trisodium phosphate; borates; tetraborates; and hydroxybenzoic acid salts. The particularly preferred alkaline chemicals are ammonium hydroxide, potassium hydroxide, lithium hydroxide and tetramethylammonium hydroxide.

The amount of the alkali/acid or the buffer may be any amount as long as pH may be maintained in the range of from 1 to 7, and is preferably from 0.0001 to 1.0 mol, and more preferably from 0.003 to 0.5 mol, in 1 liter of the polishing liquid when used in polishing.

Chelating Agent

According to need, the polishing liquid of the invention preferably contains a chelating agent (i.e., water softener) in order to minimize adverse influence by polyvalent metal ions introduced, or the like.

Examples of the chelating agents include widely-used water softeners that are a precipitation inhibitor of calcium or magnesium, and analogous compounds thereof, and examples thereof include nitrilotriacetic acid, diethylenetriaminetetraacetic acid, ethylenediaminetetraacetic acid, N,N,N-trimethylenesulfonic acid, ethylenediamine-N,N,N′,N′-tetramethylenesulfonic acid, transcyclohexanediaminetetraacetic acid, 1,2-diaminopropanetetraacetic acid, glycoletherdiaminetetraacetic acid, ethylenediamineorthohydroxyphenylacetic acid, ethylenediaminedisuccinic acid (SS form), N-(2-carboxylatoethyl)-L-asparginic acid, β-alaninediacetic acid, 2-phosphonobutane-1,2,4-tricarboxylic acid, 1-hydroxyethylidene-1,1-diphosphonic acid, N,N′-bis(2-hydroxybenzyl)ethylenediamine-N,N′-diacetic acid and 1,2-dihydroxybenzene-4,6-disulfonic acid.

The chelating agent may be used as mixtures of two or more, according to need.

The amount of the chelating agent added is an amount sufficient to seal metal ions such as polyvalent metal ions incorporated. For example, the chelating agent is added in an amount of from 0.0003 to 0.07 mol in 1 liter of the polishing liquid when used in polishing.

The polishing liquid of the invention is suitable for polishing a barrier layer that is generally present between a wiring of copper metal and/or copper alloy and an interlayer insulating film.

Barrier Metal Material

A metal of the barrier layer to be polished with the polishing liquid of the invention is generally preferably a low resistance metal material. In particular, Ta, TaN, Ti, TiN, Ru, CuMn, MnO₂, WN, W and Co are preferred, and of those, Ta and TaN are particularly preferred.

Interlayer Insulating Film

Examples of the interlayer insulating film (insulating layer) to be polished with the polishing liquid of the invention include interlayer insulating films generally used such as TEOS, and interlayer insulating films containing a low dielectric material having a dielectric constant of from about 3.5 to 2.0 (for example, organic polymer type, SiOC type, SiOF type and the like, generally called Low-k films for short).

Specific examples of the materials used for the formation of an interlayer insulating film having a low dielectric constant include HSG-R7 (trade name; a product of Hitachi Chemical Co., Ltd.), BLACK DIAMOND (trade name; a product of Applied Materials, Inc.) and the like in SiOC type.

Such a Low-k film is generally positioned under TEOS insulating film, and a barrier layer and a metal wiring are formed on the TEOS insulating film.

When the polishing liquid of the invention is used, it is possible to appropriately polish a barrier layer. Further, when the polishing liquid of the invention is applied to a substrate having a layered structure of a Low-k film and a TEOS insulating film, it is also possible to polish the TEOS insulating film at a high polishing rate, and to suppress the polishing rate at the time that the Low-k film is exposed. Accordingly, it is possible to achieve polishing by which excellent surface smoothness can be obtained and generation of scratches is suppressed.

Wiring Metal Raw Material

In the invention, the material to be polished preferably has a wiring of copper metal and/or copper alloy, such as those applied to a semiconductor device such as LSI. In particular, a copper alloy is preferred as a raw material of such a wiring. Furthermore, of the copper alloys, a copper alloy containing silver is preferred.

The content amount of silver contained in the copper alloy is preferably 40% by mass or less, more preferably 10% by mass or less, and further preferably 1% by mass or less. A copper alloy having a silver content in a range of from 0.00001 to 0.1% by mass exhibits most excellent effect.

Size of Wiring

In the invention, when the material to be polished is applied to, for example, DRAM devices, the material has a wiring having, in half pitch, of preferably 0.15 μm or less, more preferably 0.10 μm or less, and further preferably 0.08 μm or less.

On the other hand, the material to be polished is applied to, for example, MPU devices, the material has a wiring having, in half pitch, of preferably 0.12 μm or less, more preferably 0.09 μm or less, and further preferably 0.07 μm or less.

The polishing liquid of the invention exhibits particularly excellent effect to the material to be polished having the above wiring.

Polishing Method

The polishing liquid of the invention may be any of the following methods (1) to (3).

(1) The polishing liquid is prepared as a concentrated liquid and when the polishing liquid is used, the polishing liquid is diluted with water or an aqueous solution to prepare a liquid for use when used.

(2) Each component is prepared in the form of an aqueous solution as described late. These solutions are mixed, and if necessary, the mixture is diluted with water, to prepare a liquid for use.

(3) The polishing liquid is as a liquid for use.

The polishing liquid of any of the above may be applied to the polishing method using the polishing liquid of the invention.

The polishing method includes supplying a polishing liquid to a polishing pad on a polishing platen, contacting a surface to be polished of a material to be polished with the polishing pad, and subjecting the surface to be polished and the polishing pad to relative motion.

As the apparatus used for polishing, a general polishing apparatus provided with a holder for holding a material to be polished having a surface to be polished (for example, a wafer having a conductive material film formed thereon), and a polishing platen having a polishing pad attached thereto (equipped with a motor that can vary the number of rotation). As the polishing pad, a general non-woven fabric, foamed polyurethane, porous fluorine resin and the like, may be used and the polishing pad is not particularly limited. The polishing conditions are not limited, but the rotation speed of the polishing platen is preferably low rotation of 200 rpm or less such that the material to be polished does not fly out. Pressure of pressing a material to be polished having a surface to be polished (film to be polished) to the polishing pad is preferably from 0.68 to 34.5 KPa, and in order to satisfy in-plane uniformity of polishing rate to a material to be polished and flatness of a pattern, more preferably from 3.40 to 20.7 KPa.

During polishing, the polishing liquid is continuously supplied to the polishing pad by a pump or the like.

The material to be polished after completion of the polishing is well washed in flowing water, and after removing water droplets attached to the material to be polished using a spin dryer or the like, dried.

In the invention, when the concentrated liquid is diluted as in the method (1) above, the following aqueous solution may be used. The aqueous solution is previously prepared as water containing at least one of an oxidizing agent, an organic acid, additives and surfactants. The total of the components contained in the aqueous solution and the components contained in the concentrated liquid to be diluted is the components of the polishing liquid (liquid for use) used in polishing.

Thus, when the concentrated liquid is diluted with an aqueous solution and used, components that are difficult to dissolve can be blended later in a form of an aqueous solution. Therefore, a concentrated liquid that is further concentrated can be prepared.

The method of adding water or an aqueous solution to the concentrated liquid to dilute the same may be, for example, a method including merging a pipe which supplies a concentrated polishing liquid and a pipe which supplies water or an aqueous solution in the mid-course to mix the concentrated polishing liquid and water or an aqueous solution, and supplying a liquid for use of the polishing liquid mixed and diluted to a polishing pad. Mixing the concentrated liquid and water or an aqueous solution may be carried out by using any of the methods generally conducted, such as a method including colliding and mixing liquid with each other through a narrow passage while applying pressure thereto, a method including charging fillers such as glass tubes in a pipe, diverging and separating flow of liquid, merging together, and repeating this procedure, and a method of proving blades that rotate by the power in a pipe.

Supply rate of the polishing liquid is preferably from 10 to 1,000 ml/min, and more preferably from 170 to 800 ml/min in order to satisfy in-plane uniformity of the polishing rate on the surface to be polished and flatness of a pattern.

A method of polishing while diluting the concentrated liquid with water or an aqueous solution may be, for example, a method including independently providing a pipe which supplies the polishing liquid and a pipe which supplies water or an aqueous solution, supplying a given amount of a solution from the respective pipe to a polishing pad, and polishing while mixing those solutions by relative motion of the polishing pad and the surface to be polished. Alternatively, a method including placing a given amount of the concentrated liquid and water or an aqueous solution in one vessel to mix those, supplying the mixed polishing liquid to a polishing pad, and polishing may also be used.

Alternatively, a polishing method including separating components that should be contained in the polishing liquid into at least two structural components, adding water or an aqueous solution to those components to dilute the same when used, supplying the diluted liquids to a polishing pad on a polishing platen, contacting the diluted liquids with a surface to be polished, and subjecting the surface to be polished and the polishing pad to relative motion, may be used as a polishing method.

For example, in an embodiment, the components may be separated such that a structural component (A) is an oxidizing agent, and a structural component (B) is an organic acid, additives, surfactants and water, and when those components are used, the structural component (A) and the structural component (B) may be diluted with water or an aqueous solution to be used.

Furthermore, in an embodiment, additives having low solubility may be divided into two constituents (A) and (B); for example, an oxidizing agent, additives and surfactants are constituent (A) and an organic acid, additives, surfactants and water are constituent (B), and water or an aqueous solution is added to those structural components when used, thereby diluting constituent (A) and constituent (B) and using the same.

In the above embodiment, three pipes that supply constituent (A), constituent (B) and water or an aqueous solution, respectively, may be used. The mixing and diluting may be carried out by combining these three pipes into one pipe that supplies the mixture to the polishing pad, thereby mixing constituents (A) and (B) and water or an aqueous solution in the pipe. In this case, it is possible to combine two pipes into one pipe, and combining the pipe with another pipe. Specifically, a method including mixing one constituent containing additives that are poorly soluble, and the other constituent, passing the mixture of two constituents in a mixing passage that has a length sufficient to secure dissolution time, and combining thereto a pipe for water or an aqueous solution, may be employed.

Alternatively, the mixing method may be, for example, a method including directly leading three pipes respectively to the polishing pads, and mixing the liquids by relative motion of the polishing pad and the surface to be polished, as described above, or a method including mixing three constituents in one vessel, and supplying a diluted polishing liquid to the polishing pad therefrom.

In the above polishing methods, temperature of one constituent containing an oxidizing agent may be adjusted to 40° C. or lower, the other constituent(s) may be heated in a range of from room temperature to 100° C., and when the one constituent and the other constituent(s) are mixed or when water or an aqueous solution is added for dilution, the liquid temperature may be adjusted to 40° C. or lower. This method enables to increase solubility of raw materials having low solubility contained in the polishing liquid by utilizing the phenomenon that when temperature is high, solubility is increased, and is therefore a preferred method.

Raw materials that have been dissolved in the other constituent(s) by heating to a range of from room temperature to 100° C. precipitate in a solution when temperature is lowered. Therefore, when the other constituent(s) in low temperature state are used, it is necessary to previously heat to dissolve the precipitated raw materials. For this purpose, the other constituent (s) may be heated to dissolve the raw materials therein and then may be fed. Alternatively, the liquid containing precipitates may be stirred previously and then the liquid may be fed through a heated pipe to dissolve the precipitates. When the heated other constituent(s) increases the temperature of the constituents containing an oxidizing agent to 40° C. or higher, the oxidizing agent may be decomposed. Therefore, when the heated other constituent(s) and the constituent containing an oxidizing agent are mixed, it is preferred that the temperature of the mixture is 40° C. or lower.

Thus, in the invention, the components of the polishing liquid may be divided into two portions or more, and supplied to the surface to be polished. In this case, it is preferred that the components of the polishing liquid are divided into components including an oxide and components including an organic acid, and those components are supplied. Furthermore, the polishing liquid may be prepared in a form of a concentrated liquid, and the concentrated liquid and a diluting water may be separately supplied to the surface to be polished.

In the invention, when the components of the polishing liquid are divided into two portions or more and are supplied to the surface to be polished, its supply amount indicates the total of supply amount from each pipe.

Pad

The polishing pad that is used in the polishing method of the invention may be a non-foamed structure pad or a foamed structure pad. In the non-foamed structure pad, a rigid synthetic resin bulk material such as a plastic plate is used. The foamed structure pad may be either one of three types of a closed-cell foam (dry foaming system), an open-cell foam (wet foaming system) and a two layer composite (lamination system), and the two layer composite (lamination system) is particularly preferred. The foaming may be uniform or nonuniform.

Furthermore, the polishing pad may contain polishing grains generally used in polishing (for example, ceria, silica, alumina and resins). Regarding hardness, the polishing pad can be flexible or rigid, and either type can be used. In the lamination system, it is preferred to use layers having hardness different from each other. Material of the polishing pad is preferably any one of non-woven fabric, artificial leather, polyamide, polyurethane, polyester, polycarbonate and the like. The surface of the polishing pad that contacts the surface to be polished may be subjected to a processing such as forming lattice groove, hole, concentric groove, spiral groove or the like.

Wafer

A wafer as a material to be polished to which CMP is conducted with the polishing liquid of the invention has a diameter of preferably 200 mm or more, and particularly preferably 300 mm or more. The effect of the invention is remarkably exhibited when the diameter is 300 mm or more.

Polishing Apparatus

An apparatus that can carry out polishing using the polishing liquid of the invention is not particularly limited, and examples thereof include MIRRA MESA CMP and REFLEXION CMP (products of Applied Materials); FREX200 and FREX300 (products of Ebara Corporation); NPS3301 and NPS2301 (products of Nikon Corporation); A-FP-310A and A-FP-210A (products of Tokyo Seimitsu Co., Ltd.); 2300 TERES (a product of Lam Research Co., Ltd.); and MOMENTUM (a product of Speedfam IPEC).

### EXAMPLES

The present invention is described further specifically below by the Examples, but the invention is not limited to the following Examples so long as it does not depart from its aim. Unless otherwise indicated, “part” means “part by mass”, and “%” and “wt %” each mean “% by mass”.

### Example 1

A polishing liquid having the composition shown below was prepared, and polishing test was conducted.

### Composition 1:

| (1) Surface modified particle | | |
|---|---|---|
| Surface modified particle 1 as described below | 50 | g/liter |
| (2) Organic acid | | |
| Citric acid | 1.7 | g/liter |
| (3) Specific azole compound | | |
| 2-(1H-1,2,3-triazole-4-yl)succinic acid | 1.3 | g/liter |
| (4) Oxidizing agent | | |
| Hydrogen peroxide | 10 | ml |

Pure water was added to a composition having the above composition 1 to make the total amount of 1,000 ml, and pH of the solution was adjusted to 6.5 with ammonia water and nitric acid.

Surface Modified Particle 1

The surface modified particle 1 was produced by reacting 200 g of styrene-methacrylic acid copolymer particles (organic polymer particle) and 10 g of tetraisopropylbis(dioctylphosphite)titanante (specific inorganic atom-containing compound), and then adding 100 g of tetraethylorthosilicate thereto.

Evaluation of Polishing Liquid

Using an apparatus “LGP-612”, a product of Lapmaster Co., Ltd., as a polishing apparatus, each wafer shown below was polished under the following conditions while supplying a slurry.

Number of revolutions of table: 90 rpm

Number of revolutions of head: 85 rpm

Polishing pressure: 13.79 kPa

Polishing pad: POLOTEXPAD, a product of Rodel Nitta

Polishing liquid supply rate: 200 ml/min

Material to Be Polished

Material for Evaluation of Polishing Rate

An 8 inches wafer was prepared by forming a SiOC film (BLACK DIAMOND, Applied Materials, Inc.), a TEOS film, a Ta film and a copper film on a Si substrate in this order and used as a material to be polished.

Material for Scratch Evaluation An 8 inches wafer obtained b

y patterning a Low-k film and a TEOS film, prepared thorugh a photolithography step and a reactive ion etching step by a CVD method, to form a groove for wiring having a width of from 0.09 to 100 μm and a depth of 600 nm and a connecting hole, forming a Ta film having a thickness of 20 nm by a sputtering method, forming a copper film having a thickness of 50 nm by a sputtering method, and then forming a copper film having a total thickness of 1,000 nm by a plating method was used as a material to be polished.

Evaluation of Polishing Rate

Polishing rate was obtained by measuring a thickness of the TEOS film (insulating film) and the SiCO film (Low-k film) before and after CMP, respectively, and converting from the following equation.

Polishing rate (nm/min)=(Thickness before polishing−thickness after polishing)/polishing time

The allowable range of the polishing rate is from 50 to 120 nm/min, and the polishing rate of 10 nm/min or less is preferred. The results obtained are shown in Table 1.

Scratch Evaluation

The wafer for scratch evaluation was subjected to polishing to polish the TEOS film thereof and then polishing up to the SiOC film (the SiOC film was polished by 20 nm). The polished surface was washed with pure water and dried. The polished surface dried was observed with an optical microscope, and scratch evaluation was conducted based on the following evaluation criteria. It is judged that the evaluation “A” and “B” are the level that has no practical problem. The results obtained are shown in Table 1 below.

Evaluation Criteria
A: Problematic scratch was not observed.
B: 1 to 2 problematic scratches were observed on a wafer surface.
C: Many problematic scratches were observed on a wafer surface.

### Examples 2 to 17 and Comparative Examples 1 to 3

Each polishing liquid was obtained in the same manner as in the production of polishing liquid of Example 1, except for changing the composition 1 to each composition of Examples 2 to 17 and Comparative Examples 1 to 3 shown in Tables 1 and 2 below, and adjusting pH as shown in Tables 1 and 2 below, respectively. Using each polishing liquid obtained, polishing test was conducted under the same conditions as in Example 1. The results obtained are shown in Table 1 and 2 below.

TABLE 1

| | | Addition | | Addition | |
|---|---|---|---|---|---|
| | | amount | Specific azole compound | amount | |
| | Organic acid | (g/liter) | (corrosion inhibitor) | (g/liter) | Organic polymer particle |
| Example 1 | Citric acid | 1.7 | 2-(1H-1,2,3-Triazole-4- | 1.3 | Styrene-methacrylic acid |
| | | | yl)succinic acid | | copolymer particle |
| Example 2 | Oxalic acid | 1 | 1-Carboxymethyl-1H- | 0.01 | Divinylbenzene polymer |
| | | | tetrazole-5-carboxylic | | particle |
| | | | acid | | |
| Example 3 | Lactic acid | 2 | 1-(2-Carboxyphenyl)- | 0.05 | Styrene-methacrylic acid |
| | | | 1H-tetrazole-5- | | copolymer particle |
| | | | carboxylic acid | | |
| Example 4 | Malonic acid | 1.5 | 1-(4-Carboxyphenyl)- | 0.1 | Acrylic acid-methyl |
| | | | 1H-tetrazole-5- | | methacrylate copolymer |
| | | | carboxylic acid | | particle |
| Example 5 | Maleic acid | 1 | 2-(1H-Tetrazole-5-yl)- | 0.2 | Styrene-methacrylic acid |
| | | | succinic acid | | copolymer particle |
| Example 6 | Tartaric acid | 0.8 | 3-(1-(Carboxymethyl)- | 0.08 | Divinylbenzene |
| | | | 1H-tetrazole-5-yl)- | | polymer particle |
| | | | propanoic acid | | |
| Example 7 | Succinic acid | 0.6 | 1H-1,2,3-Triazole-4,5- | 0.12 | Styrene-divinylbenzene |
| | | | dicarboxylic acid | | copolymer particle |
| Example 8 | Glutaric acid | 1.2 | 1-(Carboxymethyl)-1H- | 0.02 | Styrene-methacrylic acid |
| | | | 1,2,3-triazole-4,5- | | copolymer particle |
| | | | dicarboxylic acid | | |
| Example 9 | Malic acid | 0.9 | 1-(2-Carboxymethyl)- | 0.04 | Styrene-methacrylic acid |
| | | | 1H-1,2,3-triazole-4,5- | | copolymer particle |
| | | | dicarboxylic acid | | |
| Example 10 | Adipic acid | 1.4 | 5-(Carboxymethyl)-3H- | 0.09 | Styrene-methacrylic acid |
| | | | 1,2,3-triazole-4- | | copolymer particle |
| | | | carboxylic acid | | |

| | | | | TEOS | |
|---|---|---|---|---|---|
| | Specific inorganic atom- | Addition | | polishing | Scratch |
| | containing compound | amount | | rate | performance |
| | (modifying substance) | (wt %) | pH | (nm/min) | after polishing |
| Example 1 | Tetraisopropylbis(di- | 3.3 | 6.5 | 78 | A |
| | octylphosphite)titanate, | | | | |
| | Tetraethyl ortho silicate | | | | |
| Example 2 | Isopropyldimethacryl | 3.7 | 2 | 70 | A |
| | isostearoyl titanate | | | | |
| Example 3 | Isopropyltri(dioctyl- | 4.8 | 4 | 83 | A |
| | phosphate)titanate | | | | |
| Example 4 | γ-Glycidoxypropyl- | 5.6 | 6 | 90 | A |
| | methyl dimethoxysilane | | | | |
| Example 5 | Triazine silane | 7.3 | 5 | 78 | A |
| Example 6 | Alkyl acetoacetate | 9.5 | 3 | 112 | A |
| | aluminum diacetate | | | | |
| Example 7 | Isopropyltriisostearoyl | 4.5 | 2 | 71 | A |
| | titanate | | | | |
| Example 8 | N-β(aminoethyl-γ- | 8.8 | 5 | 90 | A |
| | aminopropylmethyl | | | | |
| | dimethoxysilane | | | | |
| Example 9 | Isopropyltridecyl- | 3.5 | 4.5 | 80 | A |
| | benzenesulfonyl | | | | |
| | titanate | | | | |
| Example 10 | Isopropyltricumyl- | 2.2 | 5.5 | 75 | A |
| | phenyl titanate | | | | |

TABLE 2

| | | Addition | | Addition | |
|---|---|---|---|---|---|
| | | amount | Specific azole compound | amount | |
| | Organic acid | (g/liter) | (corrosion inhibitor) | (g/liter) | Organic polymer particle |
| Example 11 | Maleic acid | 1.2 | 1-(Carboxymethyl)-1H- | 0.2 | Acrylic acid-methyl |
| | | | 1,2,3-trizazole-4- | | methacrylate copolymer |
| | | | carboxylic acid | | particle |
| Example 12 | Tartaric acid | 0.9 | 1-(1-Carboxymethyl)- | 0.08 | Divinylbenzene |
| | | | 1H-1,2,3-trizazole-4- | | polymer particle |
| | | | carboxylic acid | | |
| Example 13 | Oxalic acid | 2 | 2-(1H-1,2,3-Triazole-1- | 0.07 | Acrylic acid-methyl |
| | | | yl)succinic acid | | methacrylate copolymer |
| | | | | | particle |
| Example 14 | Lactic acid | 1.5 | 1-(Carboxymethyl)-1H- | 0.1 | Divinylbenzene |
| | | | 1,2,3-triazole-4,5- | | polymer particle |
| | | | dicarboxylic acid | | |
| Example 15 | Malonic acid | 1 | 1-(2-Carboxymethyl)- | 0.05 | Acrylic acid-methyl |
| | | | 1H-1,2,3-triazole-4,5- | | methacrylate copolymer |
| | | | dicarboxylic acid | | particle |
| Example 16 | Maleic acid | 1.2 | 1-(4-Carboxyphenyl)- | 0.02 | Divinylbenzene |
| | | | 1H-tetrazole-5- | | polymer particle |
| | | | carboxylic acid | | |
| Example 17 | Oxalic acid | 0.9 | 2-(1H-Tetrazole-5-yl)- | 0.05 | Acrylic acid-methyl |
| | | | succinic acid | | methacrylate copolymer |
| | | | | | particle |
| Comparative | Acetic acid | 0.2 | 1,2,3-Benzotriazole | 0.1 | Colloidal silica |
| Example 1 | | | | | |
| Comparative | Acetic acid | 0.1 | 1,2,3-Benzotriazole | 0.05 | Colloidal silica |
| Example 2 | | | | | |
| Comparative | Acetic acid | 0.5 | 1,2,3-Benzotriazole | 0.08 | Colloidal silica |
| Example 3 | | | | | |

| | | | | TEOS | |
|---|---|---|---|---|---|
| | Specific inorganic atom- | Addition | | polishing | Scratch |
| | containing compound | amount | | rate | performance |
| | (modifying substance) | (wt %) | pH | (nm/min) | after polishing |
| Example 11 | Tetraoctylbis(ditri- | 5.6 | 5 | 88 | A |
| | dodecylphosphite)- | | | | |
| | titanate | | | | |
| Example 12 | Tetra(2,2-diallyloxy- | 7.3 | 4.5 | 95 | A |
| | methyl-1-butyl)bis(di- | | | | |
| | tridecyl)phosphite | | | | |
| | titanate | | | | |
| Example 13 | Bis(dioctylpyro- | 9.5 | 5 | 96 | A |
| | phosphate)oxyacetate | | | | |
| Example 14 | Isopropyltri(N-amide- | 8.8 | 3 | 84 | A |
| | ethyl•aminoethyl) | | | | |
| | titanate | | | | |
| Example 15 | N-3-(4-(3-Aminopropoxy) | 3.5 | 6.5 | 96 | A |
| | butoxy)propyl- | | | | |
| | 3-aminopropyltri- | | | | |
| | methoxysilane | | | | |
| Example 16 | Isopropyltri(dioctyl- | 2.2 | 2 | 88 | A |
| | phosphate)titanate | | | | |
| Example 17 | Isopropyltricumyl- | 4.7 | 3 | 85 | A |
| | phenyl titanate | | | | |
| Comparative | None | 3.5 | 8 | 50 | B |
| Example 1 | | | | | |
| Comparative | None | 4.2 | 8.5 | 45 | C |
| Example 2 | | | | | |
| Comparative | None | 3.5 | 8.5 | 48 | C |
| Example 3 | | | | | |

According to Table 1 and Table 2, when the polishing liquids of Examples 1 to 17 were used, polishing rate of TEOS was high and scratch performance was excellent as compared with Comparative Examples 1 to 3. On the other hand, the polishing liquids of Comparative Examples 1 to 3 were poor in each of TEOS polishing rate and scratch performance as compared with the polishing liquids of the Examples.

From the above, it is found that the polishing liquid of the invention has excellent TEOS polishing rate, and further has excellent scratch performance.

According to the invention, it is possible to provide a polishing liquid that includes organic polymer particles having sufficient surface strength and hardness, and that has excellent heat resistance and suitable flexibility and, by using the polishing liquid, it is possible to increase the polishing rate and suppress generation of scratches.

The exemplary embodiments of the invention will be described below, but the invention is not limited to the following exemplary embodiments.

<1> A polishing liquid for polishing a barrier layer of a semiconductor integrated circuit, the polishing liquid comprising surface modified particles that comprise organic polymer particles having at least one inorganic atom selected from the group consisting of Ti, Al, Zr and Si bonded to the organic polymer particles via an oxygen atom present on a surface of the organic polymer particles, an organic acid, an azole compound comprising at least two carboxyl groups, and an oxidizing agent, the polishing liquid having a pH of from 1 to 7.

<2> The polishing liquid of <1>, wherein the organic acid is at least one selected from the group consisting of oxalic acid, citric acid, lactic acid, malonic acid, succinic acid, glutaric acid, adipic acid, maleic acid, malic acid, tartaric acid and derivatives thereof.

<3> The polishing liquid of <1> or <2>, wherein the concentration of the surface modified particles is from 0.5 to 15% by mass based on the total mass of the polishing liquid.

<4> The polishing liquid of any one of <1> to <3>, wherein the surface modified particles have a primary average particle size in a range of from 20 to 150 nm.

<5> The polishing liquid of any one of <1> to <4>, wherein the barrier layer comprises at least one metal selected from the group consisting of Ta, TaN, Ti, TiN, Ru, CuMn, MnO2, WN, W and Co.

<6> A polishing method for polishing a barrier layer of a semiconductor integrated circuit, the method comprising:

supplying, to a polishing pad on a polishing platen, a polishing liquid comprising surface modified particles that comprise organic polymer particles having at least one inorganic atom selected from the group consisting of Ti, Al, Zr and Si bonded to the organic polymer particles via an oxygen atom on a surface of the organic polymer particles, an organic acid, an azole compound comprising at least two carboxyl groups, and an oxidizing agent, the polishing liquid having a pH of from 1 to 7; and

contacting a surface to be polished of a material to be polished with the polishing pad and subjecting the surface to be polished and the polishing pad to relative motion.

<7> The polishing method of <6>, wherein the organic acid is at least one selected from the group consisting of oxalic acid, citric acid, lactic acid, malonic acid, succinic acid, glutaric acid, adipic acid, maleic acid, malic acid, tartaric acid and their derivatives.

<8> The polishing method <6> or <7>, wherein the concentration of the surface modified particles is from 0.5 to 15% by mass based on the total mass of the polishing liquid.

<9> The polishing method of any one of <6> to <8>, wherein the surface modified particles have a primary average particle size in a range of from 20 to 150 nm.

<10> The polishing method of any one of <6> to <9>, wherein the barrier layer comprises at least one metal selected from the group consisting of Ta, TaN, Ti, TiN, Ru, CuMn, MnO₂, WN, W and Co.

All publications, patent applications, and technical standards mentioned in this specification are herein incorporated by reference to the same extent as if each individual publication, patent application, or technical standard was specifically and individually indicated to be incorporated by reference.

What is claimed is:

1. A polishing liquid for polishing a barrier layer of a semiconductor integrated circuit, the polishing liquid comprising surface modified particles that comprise organic polymer particles having at least one inorganic atom selected from the group consisting of Ti, Al, Zr and Si bonded to the organic polymer particles via an oxygen atom present on a surface of the organic polymer particles, an organic acid, an azole compound comprising at least two carboxyl groups, and an oxidizing agent, the polishing liquid having a pH of from 1 to 7.

2. The polishing liquid of claim 1, wherein the organic acid is at least one selected from the group consisting of oxalic acid, citric acid, lactic acid, malonic acid, succinic acid, glutaric acid, adipic acid, maleic acid, malic acid, tartaric acid and derivatives thereof.

3. The polishing liquid of claim 1, wherein the concentration of the surface modified particles is from 0.5 to 15% by mass based on the total mass of the polishing liquid.

4. The polishing liquid of claim 1, wherein the surface modified particles have a primary average particle size in a range of from 20 to 150 nm.

5. The polishing liquid of claim 1, wherein the barrier layer comprises at least one metal selected from the group consisting of Ta, TaN, Ti, TiN, Ru, CuMn, MnO₂, WN, W and Co.

6. A polishing method for polishing a barrier layer of a semiconductor integrated circuit, the method comprising:
supplying, to a polishing pad on a polishing platen, a polishing liquid comprising surface modified particles that comprise organic polymer particles having at least one inorganic atom selected from the group consisting of Ti, Al, Zr and Si bonded to the organic polymer particles via an oxygen atom present on a surface of the organic polymer particles, an organic acid, an azole compound comprising at least two carboxyl groups, and an oxidizing agent, the polishing liquid having a pH of from 1 to 7; and
contacting a surface to be polished of a material to be polished with the polishing pad and subjecting the surface to be polished and the polishing pad to relative motion.

7. The polishing method of claim 6, wherein the organic acid is at least one selected from the group consisting of oxalic acid, citric acid, lactic acid, malonic acid, succinic acid, glutaric acid, adipic acid, maleic acid, malic acid, tartaric acid and their derivatives.

8. The polishing method of claim 6, wherein the concentration of the surface modified particles is from 0.5 to 15% by mass based on the total mass of the polishing liquid.

9. The polishing method of claim 6, wherein the surface modified particles have a primary average particle size in a range of from 20 to 150 nm.

10. The polishing method of claim 6, wherein the barrier layer comprises at least one metal selected from the group consisting of Ta, TaN, Ti, TiN, Ru, CuMn, MnO₂, WN, W and Co.
